(19) United States
(12) Patent Application Publication
(10) Pub. No.: US 2026/0255649 A1
(43) Pub. Date: Aug. 27, 2026

(54) SEMICONDUCTOR DEVICE AND MANUFACTURING METHOD THEREOF

(71) Applicant: Kioxia Corporation, Tokyo (JP)

(72) Inventor: Shota YAMAGIWA, Yokkaichi Mie (JP)

(73) Assignee: Kioxia Corporation, Tokyo (JP)

(21) Appl. No.: 19/238,688

(22) Filed: Jun. 16, 2025

(30) Foreign Application Priority Data
Feb. 21, 2025 (JP) 2025-027124

(51) Int. Cl. H10D 64/23; H10D 64/01

(52) U.S. Cl. CPC H10D 64/251; H10D 64/01

(57) ABSTRACT

A semiconductor device according to the present embodiment includes a wiring layer and a columnar electrode. The wiring layer includes a plurality of wirings. The columnar electrode is provided integrally with the wiring and extends from a bottom of the wiring in a direction substantially perpendicular to the wiring layer. A width of an upper end of the columnar electrode is smaller than a width of a middle portion between the upper end and a lower end of the columnar electrode.

### CROSS REFERENCE TO RELATED APPLICATIONS

This application is based upon and claims the benefit of priority from the prior Japanese Patent Application No. 2025-027124, filed on Feb. 21, 2025, the entire contents of which are incorporated herein by reference.

### FIELD

The embodiments of the present invention relate to a semiconductor device and a manufacturing method thereof.

### BACKGROUND

In some semiconductor devices, a contact (columnar electrode) is provided in a lower portion of one of wirings in a wiring layer. The distance between the contact and the other wiring is preferably widened in terms of reliability of withstand voltage and the like. With the widths of the contact and the wiring reduced, the distance between the contact and the wiring can be increased, while the resistance of the contact and the wiring increases at the same time. Thus, it is preferable that the distance between the contact and the wiring be increased while maintaining dimensions of the structure contributing to the resistance.

### BRIEF DESCRIPTION OF THE DRAWINGS

FIG. 1 is a view illustrating an example of the configuration of a semiconductor device according to a first embodiment.

FIG. 2A is a view sequentially illustrating a part of the procedure of a manufacturing method of the semiconductor device according to the first embodiment.

FIG. 2B is a view sequentially illustrating a part of the procedure of the manufacturing method of the semiconductor device subsequent to FIG. 2A.

FIG. 2C is a view sequentially illustrating a part of the procedure of the manufacturing method of the semiconductor device subsequent to FIG. 2B.

FIG. 2D is a view sequentially illustrating a part of the procedure of the manufacturing method of the semiconductor device subsequent to FIG. 2C.

FIG. 3 is a view illustrating an example of the configuration of the semiconductor device according to a first modification of the first embodiment.

FIG. 4 is a view illustrating an example of the configuration of the semiconductor device according to a second modification of the first embodiment.

FIG. 5 is a view illustrating an example of the configuration of the semiconductor device according to a second embodiment.

FIG. 6A is a view sequentially illustrating a part of the procedure of the manufacturing method of the semiconductor device according to the second embodiment.

FIG. 6B is a view sequentially illustrating a part of the procedure of the manufacturing method of the semiconductor device subsequent to FIG. 6A.

FIG. 6C is a view sequentially illustrating a part of the procedure of the manufacturing method of the semiconductor device subsequent to FIG. 6B.

FIG. 6D is a view sequentially illustrating a part of the procedure of the manufacturing method of the semiconductor device subsequent to FIG. 6C.

FIG. 6E is a view sequentially illustrating a part of the procedure of the manufacturing method of the semiconductor device subsequent to FIG. 6D.

FIG. 7 is a view illustrating an example of the configuration of the semiconductor device according to a third embodiment.

FIG. 8 is a view sequentially illustrating a part of the procedure of a manufacturing method of the semiconductor device according to the third embodiment.

FIG. 9 is a view illustrating an example of the configuration of the semiconductor device according to a fourth embodiment.

FIG. 10 is a block diagram of a semiconductor memory device according to another embodiment.

FIG. 11 is an equivalent circuit diagram illustrating an example of the configuration of a memory cell array and a row decoder included in the semiconductor memory device according to the other embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a wiring layer and a columnar electrode. The wiring layer includes a plurality of wirings. The columnar electrode is provided integrally with the wiring and extends from a bottom of the wiring in a direction substantially perpendicular to the wiring layer. A width of an upper end of the columnar electrode is smaller than a width of a middle portion between the upper end and a lower end of the columnar electrode.

### First Embodiment

Hereinafter, an embodiment will be described in detail with reference to the drawings.

### Configuration of Semiconductor Device

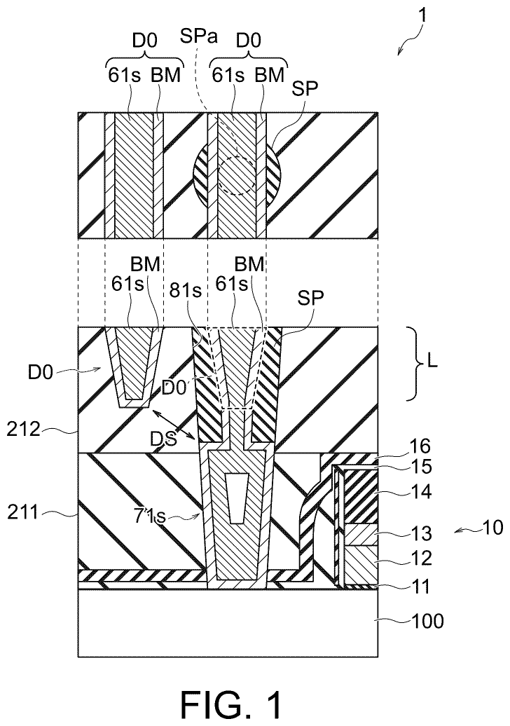

FIG. 1 is a view illustrating an example of the configuration of a semiconductor device 1 according to a first embodiment. The upper side of FIG. 1 shows a top view. The lower side of FIG. 1 shows a cross-sectional view. Note that in the present description, a surface of a substrate 100 on which a transistor 10 and the like described later are formed is defined as an upper surface, and a direction in which a polysilicon electrode 12, a metal electrode 13, and the like of the transistor 10 are stacked is defined as an upper side of the semiconductor device 1.

As illustrated in FIG. 1, the semiconductor device 1 includes the transistor 10, interlayer insulation layers 211 and 212, a contact 71s, and a wiring D0 that are provided on the substrate 100.

The substrate 100 is, for example, a semiconductor substrate such as a silicon substrate. In the formation region of the transistor 10 in the substrate 100, a dopant of a predetermined conductivity type is diffused to form a source/drain region.

A plurality of transistors 10 is provided on the substrate 100.

The transistor 10 is configured as, for example, a metal oxide semiconductor (MOS) transistor.

The transistor 10 includes a gate insulation layer 11, the polysilicon electrode 12, the metal electrode 13, and a cap layer 14, which are stacked in this order from the substrate 100 side. The polysilicon electrode 12 and the metal electrode 13 constitute a gate electrode of the transistor 10. In other words, the transistor 10 is configured as a transistor having a poly/metal gate structure.

In addition, the transistor 10 includes a spacer layer 15 that covers side surfaces of the gate insulation layer 11, the polysilicon electrode 12, the metal electrode 13, and the cap layer 14 and an upper surface of the cap layer 14, and a liner layer 16 that covers the spacer layer 15.

Here, the gate insulation layer 11 of the transistor 10 is, for example, a silicon oxide layer, a hafnium oxide layer, or a zirconium oxide layer.

In addition, the polysilicon electrode 12 is, for example, a conductive polysilicon layer and functions as a poly gate as described above. Further, the metal electrode 13 is, for example, a tungsten silicide layer and functions as a metal gate as described above.

Further the cap layer 14, the spacer layer 15, and the liner layer 16 are all insulation layers. The cap layer 14 and the liner layer 16 are, for example, a nitride layer such as a silicon nitride layer, and the spacer layer 15 is an oxide layer such as a silicon oxide layer. More specifically, the spacer layer 15 is, for example, a tetra ethoxy silane (TEOS) layer.

Further, these transistors 10 are entirely covered with the interlayer insulation layers 211 and 212. The interlayer insulation layer 211 is, for example, a silicon oxide layer such as a non-doped silicate glass (NSG) layer and directly covers the transistors 10. The interlayer insulation layer 212 is, for example, a silicon oxide layer such as a TEOS layer and covers the transistors 10 via the interlayer insulation layer 211.

The contact 71s is connected to the transistor 10.

The contact 71s penetrates the interlayer insulation layers 212 and 211, the liner layer 16, and the spacer layer 15 and is connected to the source/drain region provided in the substrate 100 on both sides of the polysilicon electrode 12 and the metal electrode 13 of the transistor 10. The contact 71s includes a conductive layer 61s.

The conductive layer 61s penetrates the interlayer insulation layers 212 and 211, the liner layer 16, and the spacer layer 15 and reaches the substrates 100 on both sides of the transistor 10. The conductive layer 61s is a single metal layer, a metal layer having a barrier metal layer on its surface, or the like. The conductive layer 61s is, for example, a metal layer such as a tungsten layer or a copper layer. The barrier metal layer may be, for example, a titanium layer, a titanium nitride layer, a tantalum layer, or a tantalum nitride layer.

The contact 71s is connected, at its upper end, to the wiring D0 provided in the interlayer insulation layer 212. The wiring D0 is, for example, a metal layer such as a tungsten layer or a copper layer. The wiring D0 may be a metal layer or the like having a barrier metal layer BM on its surface.

In this manner, the individual transistor 10 is connected to a power supply, a semiconductor element, and the like (not illustrated) via the contact 71s and a plurality of wirings D0.

In addition, the transistor 10 is used as a drive circuit that drives the semiconductor element or the like electrically connected to the transistor 10.

The semiconductor device 1 illustrated in FIG. 1 further includes a wiring layer L, a barrier metal layer BM, and a spacer SP.

The wiring layer L includes a plurality of wirings D0. The example illustrated in FIG. 1 shows two wirings D0.

The contact 71s is provided integrally (integral formation) with the wiring D0 denoted by a broken line in the cross-sectional view. That is, the conductive layer 61s and the barrier metal layer BM are continuously provided between the contact 71s and the wiring D0. The contact 71s extends, in a direction substantially perpendicular to the wiring layer L, from a bottom of the wiring D0 denoted by the broken line in the cross-sectional view.

A distance Ds illustrated in FIG. 1 is a distance between the contact 71s and a wiring D0 adjacent to the wiring D0 that is connected to the contact 71s. The distance Ds can be increased by means of the spacer Sp. In this manner, the withstand voltage can be improved. That is, the reliability can be improved.

The spacer SP is provided between the wiring D0 on an upper side of the contact 71s and the interlayer insulation layer 212 and between an upper end of the contact 71s and the interlayer insulation layer 212. That is, the spacer SP is provided on a side surface of the wiring D0 on the upper side of the contact 71s and a side surface of the upper end of the contact 71s. Due to the width of the spacer SP, the width of the wiring D0 is smaller than the width of a contact hole 81s. Note that the width is a width in a direction substantially parallel to the wiring layer L. The width of the upper end of the contact 71s is smaller than the width of a middle portion between the upper end and a lower end of the contact 71s. That is, the width of the upper end of the contact 71s can be reduced by means of the spacer SP.

Note that the width of the middle portion of the contact 71s is larger than the width of each of the upper end and the lower end of the contact 71s. That is, the width of the contact 71s is largest in the middle portion. Therefore, the cross-sectional shape of the contact 71s may be, for example, an arcuate shape.

Further, by means of the spacer SP, the position at which the width of the contact 71s is largest can be situated further lower. That is, the position at which the width of the contact 71s is largest is situated lower relative to the bottom of the wiring D0 along a direction substantially perpendicular to the wiring layer L.

### Manufacturing Method of Semiconductor Device

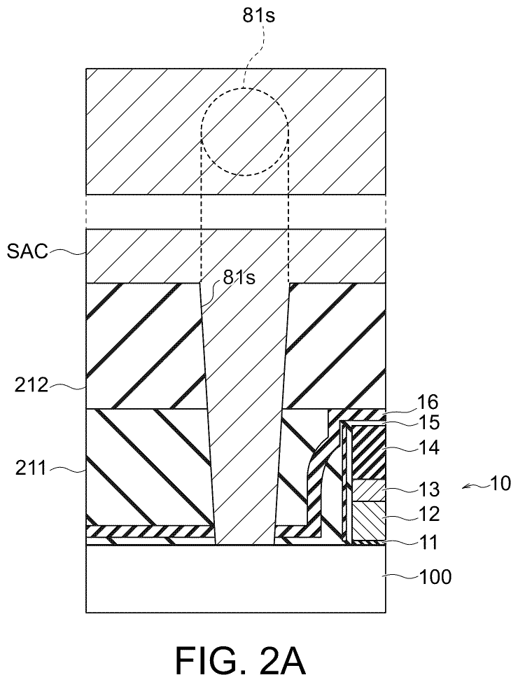

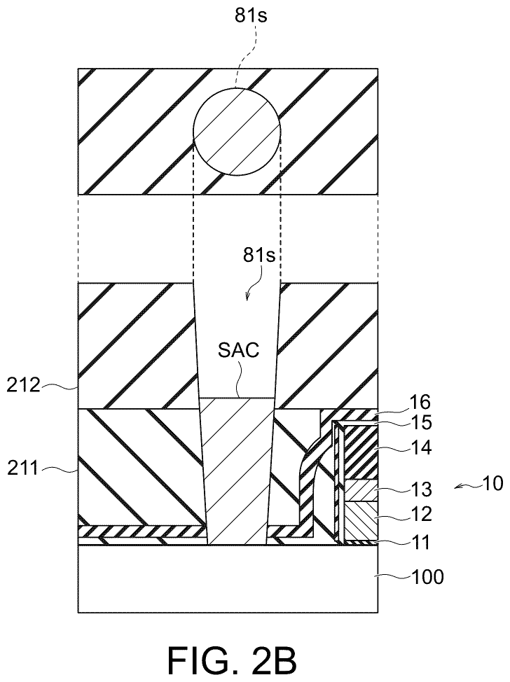

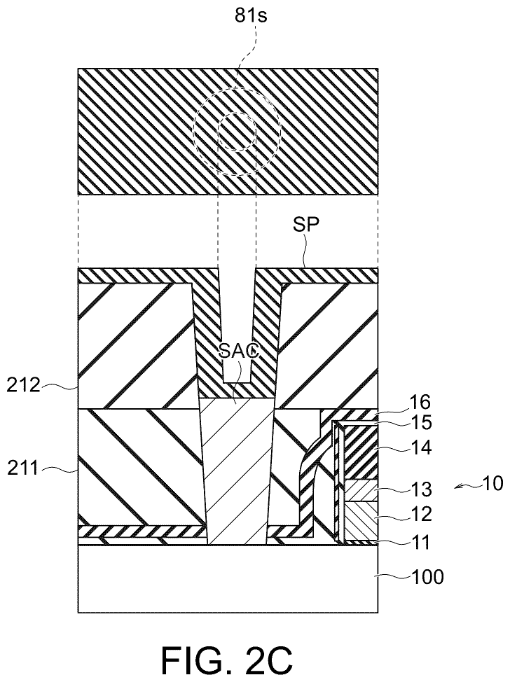

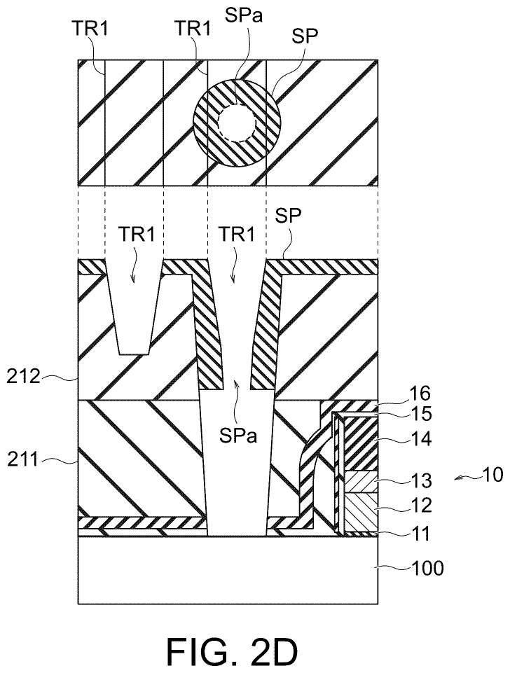

Next, a manufacturing method of the semiconductor device 1 according to the first embodiment will be described with reference to FIGS. 2A to 2D. FIGS. 2A to 2D are cross-sectional views sequentially illustrating a part of the procedure of the manufacturing method of the semiconductor device 1 according to the first embodiment.

First, as illustrated in FIG. 2A, a dopant of a predetermined conductivity type is diffused into the substrate 100 such as a silicon substrate. Further, the gate insulation layer 11, the polysilicon electrode 12, the metal electrode 13, and the cap layer 14 are formed on the substrate 100. Furthermore, the spacer layer 15 is formed which covers each of the side surfaces of the gate insulation layer 11, the polysilicon electrode 12, the metal electrode 13, and the cap layer 14, and the upper surface of the cap layer 14. In addition, the liner layer 16 that covers the spacer layer 15 is formed. Thus, the transistor 10 is formed.

Further, the interlayer insulation layer 211 such as an NSG layer that covers the transistor 10 is formed. Furthermore, the interlayer insulation layer 212 such as a TEOS layer that covers the interlayer insulation layer 211 is formed. In addition, the interlayer insulation layers 212 and 211 are etched to form the contact hole 81s.

The liner layer 16 and the spacer layer 15 on a bottom surface of the contact hole 81s are removed to expose the upper surface of the substrate 100.

Further, a sacrificial film SAC is embedded in the contact hole 81s. The sacrificial film SAC includes, for example, a carbon-based material.

Next, as illustrated in FIG. 2B, the sacrificial film SAC is etched back. As a result, a part of the sacrificial film SAC in the contact hole 81s is removed so that the sacrificial film SAC in the contact hole 81s is recessed.

Next, as illustrated in FIG. 2C, the spacer SP is formed on an inner side surface of the contact hole 81s and on the sacrificial film SAC. The spacer SP is, for example, an insulation film. The spacer SP includes, for example, a silicon oxide.

Next, as illustrated in FIG. 2D, a trench TR1 passing through the contact hole 81s is formed in the interlayer insulation layer 212 and an opening SPa is formed in the spacer SP on the sacrificial film SAC. Note that a plurality of trenches TR1 (for example, two trenches TR1) is provided in the interlayer insulation layer 212. The opening SPa is formed simultaneously with the trench TR1 by, for example, lithography and RIE for forming the trench TR1. Further, the sacrificial film SAC is removed via the opening SPa. Furthermore, by performing pretreatment for metal film deposition, an oxide film (not illustrated) of the substrate 100 formed by natural oxidation is removed. The pretreatment is, for example, a hydrofluoric acid-based treatment. Note that the pretreatment may be changed in accordance with the material or the structure of the substrate 100. Note that the pretreatment may not be necessarily performed.

Thereafter, the barrier metal layer BM and the conductive layer 61s are embedded in the contact hole 81s and the trench TR1. In this manner, the contact 71s and the wiring D0 are formed. Further, chemical mechanical polishing (CMP) is performed so as to expose the interlayer insulation layer 212.

In this way, the semiconductor device 1 illustrated in FIG. 1 is manufactured.

As described above, according to the first embodiment, the contact 71s is provided integrally with the wiring D0. This can suppress an increasing resistance between the contact 71s and the wiring D0. As a result, the chip size can be reduced without requiring to enlarge the contact area between the contact 71s and the wiring D0.

Further, in the first embodiment, the width of the upper end of the contact 71s is smaller than the width of the middle portion between the upper end and the lower end of the contact 71s. This is because the spacer SP is formed. Thus, the distance Ds between the contact 71s and the other wiring D0 can be increased. As a result, the withstand voltage can be improved.

Further, the position at which the width of the contact 71s is largest is situated lower relative to the bottom of the wiring D0 along a direction substantially perpendicular to the wiring layer L. This can further increase the distance Ds. As a result, the withstand voltage can be further improved.

Note that by adjusting the etch-back amount of the sacrificial film SAC in the process illustrated in FIG. 2B, the length of the upper end of the contact 71s, that is, the position at which the width of the contact 71s is largest can be adjusted. That is, the distance Ds illustrated in FIG. 1 can be further increased.

To increase the distance Ds, the widths of the contact 71s and the wiring D0 are reduced in some cases. However, in such cases, the resistance of the contact 71s and the wiring D0 could increase. Further, the releasability of the contact 71s could be deteriorated.

By contrast, in the first embodiment, since the widths of the contact 71s and the wiring D0 are not reduced, the withstand voltage can be improved while suppressing the increasing resistance and deteriorated releasability.

Further, the contact 71s illustrated in FIG. 1 is connected to the source region or the drain region of the transistor 10, but is not limited thereto. The contact 71s can be applied to a contact connected to the metal electrode 13 of the transistor 10. In addition, the contact 71s can also be applied to any contact (via) connected to the wiring, regardless of the device structure.

### First Modification of First Embodiment

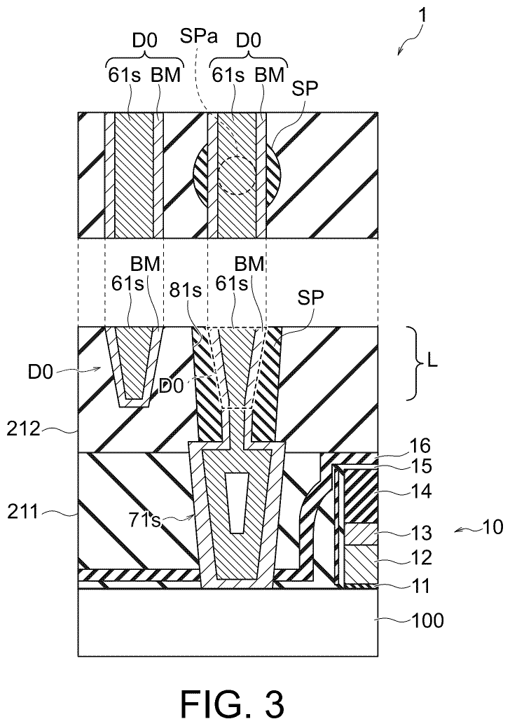

FIG. 3 is a cross-sectional view illustrating an example of the configuration of the semiconductor device 1 according to a first modification of the first embodiment. The first modification of the first embodiment is different from the first embodiment in that a part of the interlayer insulation layer 211 is removed by pretreatment.

By the pretreatment in the process illustrated in FIG. 2D, a part of the interlayer insulation layer 211 is etched away. Note that a part of the spacer SP may also be etched away, but the spacer SP is not completely removed.

With a part of the interlayer insulation layer 211 being etched away, the width of the contact 71s below the spacer SP increases. The etch-away amount of the interlayer insulation layer 211 depends on, for example, the amount of hydrofluoric acid-based solution in the pretreatment.

As in the first modification of the first embodiment, a part of the interlayer insulation layer 211 may be removed by the pretreatment. This case also allows the same effects as those of the first embodiment to be obtained.

### Second Modification of First Embodiment

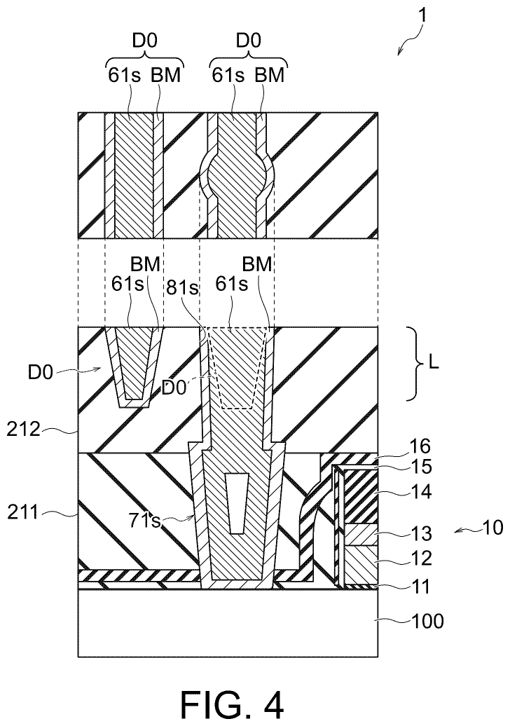

FIG. 4 is a cross-sectional view illustrating an example of the configuration of the semiconductor device 1 according to a second modification of the first embodiment. The second modification of the first embodiment is different from the first modification of the first embodiment in that the spacer SP is removed by the pretreatment.

By the pretreatment in the process illustrated in FIG. 2D, a part of the interlayer insulation layer 211 is etched away and the spacer SP is completely removed.

Note that a part of the upper end of the contact 71s may contact the side surface of the wiring D0.

As in the second modification of the first embodiment, the spacer SP may be removed by the pretreatment. This case also allows the same effects as those of the first modification of the first embodiment to be obtained.

### Second Embodiment

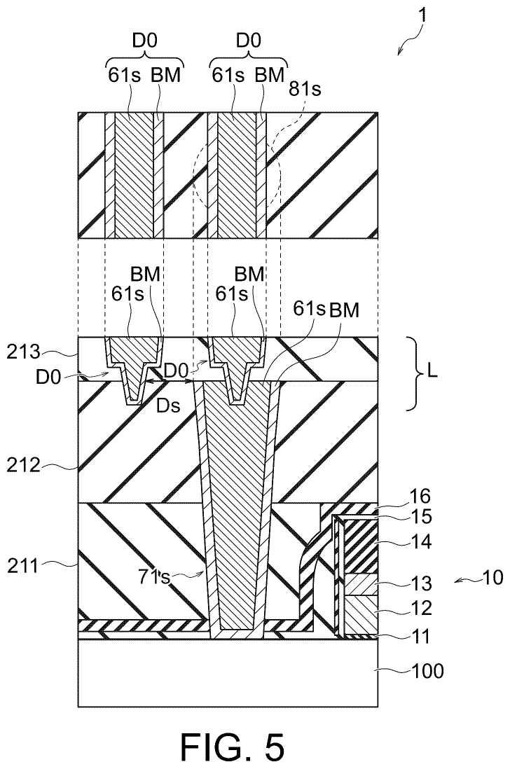

FIG. 5 is a view illustrating an example of the configuration of the semiconductor device 1 according to a second embodiment. The second embodiment is different from the first embodiment in that the side surface of the wiring D0 is in a step shape and the contact 71s and the wiring D0 are separately formed.

The wiring D0 has a step shape with an upper step having a width larger than the width of a lower step. A tip end of the wiring D0 reaches the contact 71s.

The contact 71s is provided separately from the wiring D0. That is, the barrier metal layer BM is provided between the contact 71s and the wiring D0 on the upper side of the contact 71s. Further, the conductive layer 61s of the contact 71s and the conductive layer 61s of the wiring D0 may be a metal layer of the same type or different types.

With the width at the tip end of the wiring D0 reduced, the distance Ds can be increased. In this manner, the withstand voltage can be improved. That is, the reliability can be improved. Note that since the width of an upper portion of the wiring D0 is large, an increasing resistance can be suppressed.

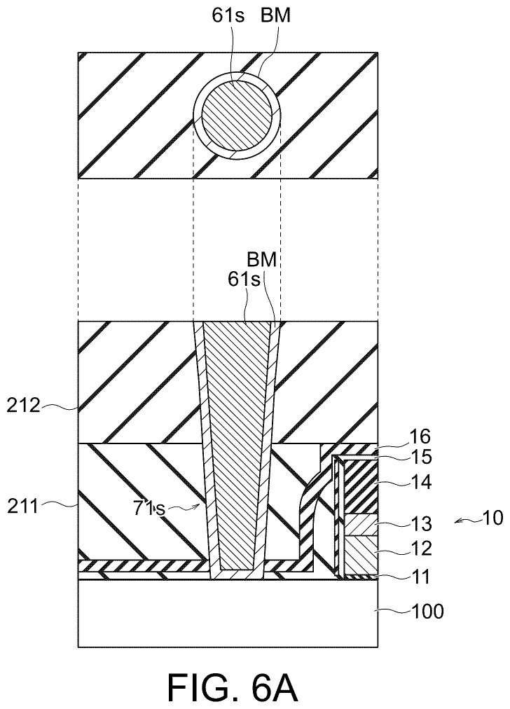

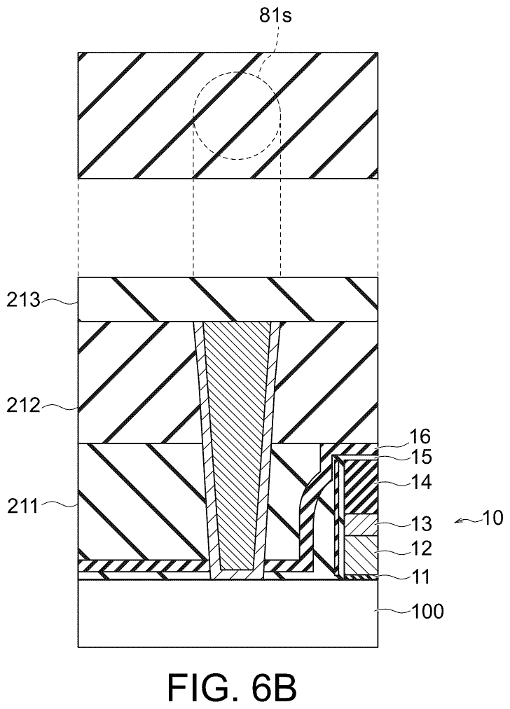

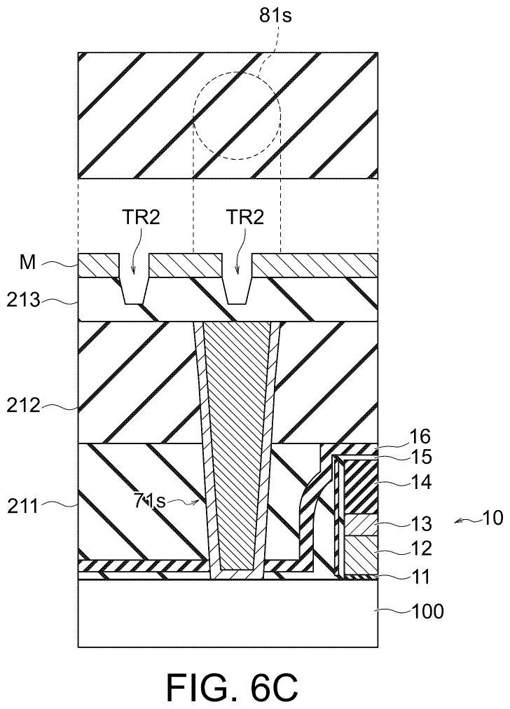

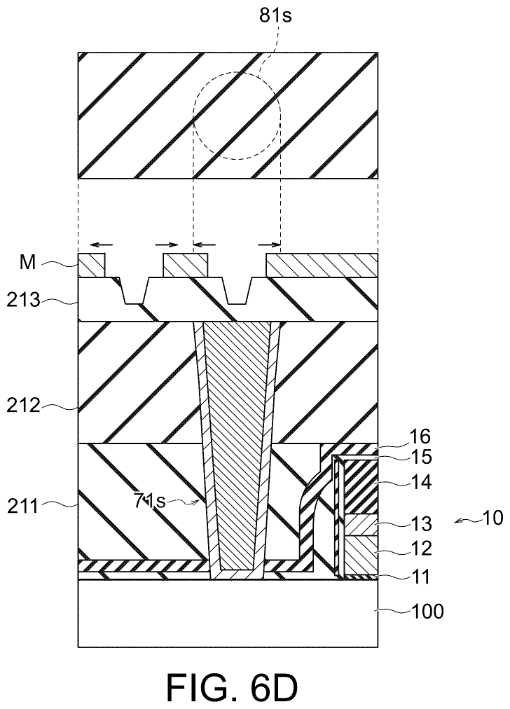

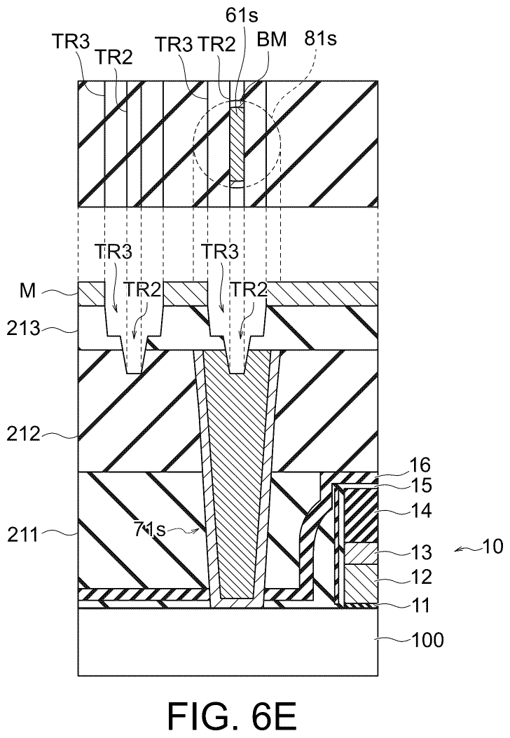

FIGS. 6A to 6E are views sequentially illustrating a part of the procedure of the manufacturing method of the semiconductor device 1 according to the second embodiment.

First, as described with reference to FIG. 2A, the transistor 10 is formed, the interlayer insulation layers 211 and 212 are formed, and the contact hole 81s is formed in the interlayer insulation layers 211 and 212.

Next, as illustrated in FIG. 6A, the barrier metal layer BM and the conductive layer 61s are embedded in the contact hole 81s. In this manner, the contact 71s is formed. Further, CMP is performed so as to expose the interlayer insulation layer 212.

Next, as illustrated in FIG. 6B, an interlayer insulation layer 213 is formed on the interlayer insulation layer 212. The interlayer insulation layer 213 is, for example, a silicon oxide layer such as a TEOS layer.

Next, as illustrated in FIG. 6C, a mask M having a first pattern corresponding to the width of a lower portion of the wiring D0 is formed. The mask M is, for example, a carbon-based material. Further, using the mask M as a mask, a trench TR2 passing through the contact hole 81s is formed in the interlayer insulation layer 213. The trench TR2 passes through the contact 71s as viewed from a direction substantially perpendicular to the wiring layer L. The trench TR2 is formed by, for example, performing RIE halfway through.

Next, as illustrated in FIG. 6D, slimming of the mask M is performed. The slimming of the mask M is performed by, for example, using an oxygen-based plasma. The mask M after the slimming has a second pattern corresponding to the width of the upper portion of the wiring D0.

Next, as illustrated in FIG. 6E, using the slimmed mask M as a mask, a trench TR3 passing through the contact hole 81s is formed in the interlayer insulation layer 213. The trench TR3 has a width larger than the width of the trench TR2. The trench TR3 passes through the contact 71s as viewed from a direction substantially perpendicular to the wiring layer L. The trench TR3 is formed so as to allow the trench TR2 to reach the contact 71s. The trench TR3 is formed by, for example, resuming RIE by which the trench TR2 was formed. Note that the conductive layer 61s is also etched away.

Thereafter, the barrier metal layer BM and the conductive layer 61s are embedded in the trenches TR2 and TR3. In this manner, the wiring D0 is formed. Further, CMP is performed so as to expose the interlayer insulation layer 213.

In this way, the semiconductor device 1 illustrated in FIG. 5 is manufactured.

To increase the distance Ds while suppressing the increasing resistance, the shape of the side surface of the wiring D0 is formed in a taper shape so as to be flattened (increase the taper angle) in some cases. However, in this case, the distance Ds could vary due to variations in the film thickness of the interlayer insulation layer 212 or variations in RIE.

By contrast, in the second embodiment, since the shape of the side surface of the wiring D0 is in a step shape, the lower portion of the wiring D0 can be made steeper (reduce the taper angle). In this manner, variations in the distance Ds between the contact 71s and the wiring D0 can be suppressed.

As in the second embodiment, the side surface of the wiring D0 may be in a step shape and the contact 71s and the wiring D0 may be separately formed. This case also allows the same effects as those of the first embodiment to be obtained.

### Third Embodiment

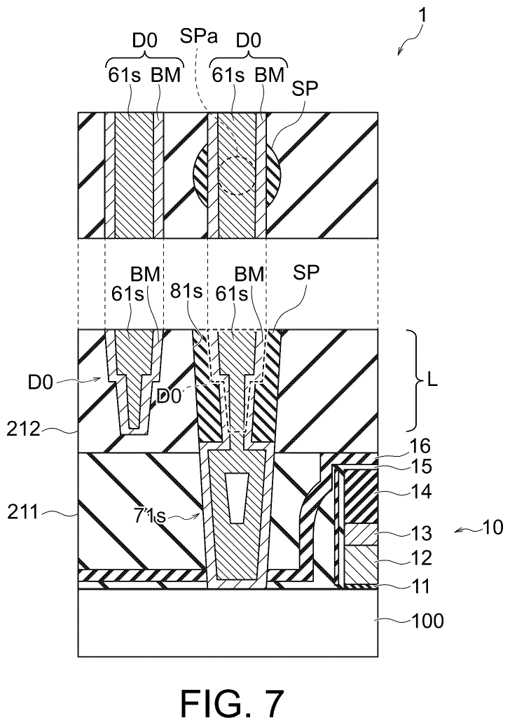

FIG. 7 is a view illustrating an example of the configuration of the semiconductor device 1 according to a third embodiment. The third embodiment is different from the first embodiment in that the side surface of the wiring D0 is in a step shape. That is, the third embodiment is also a combination of the first embodiment and the second embodiment.

The wiring D0 has a step shape with an upper step having a width larger than the width of a lower step.

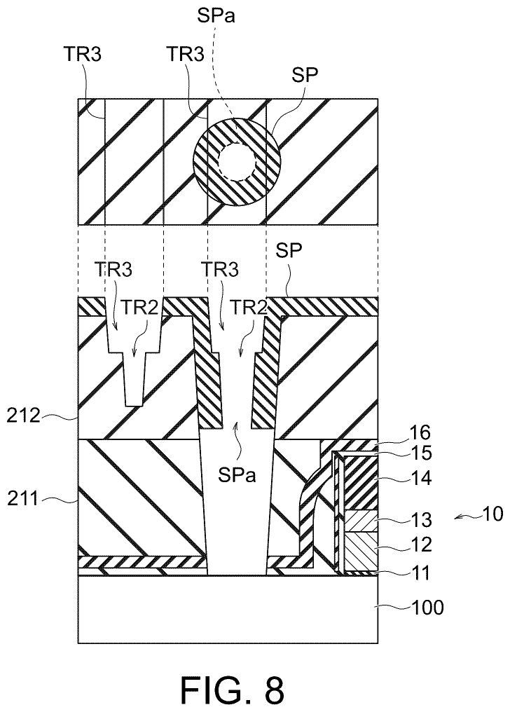

FIG. 8 is a view sequentially illustrating a part of the procedure of the manufacturing method of the semiconductor device 1 according to the third embodiment. The process illustrated in FIG. 8 is performed after the same processes as those of FIGS. 2A to 2C.

After the spacer SP is formed (see FIG. 2C), the trench TR2 passing through the contact hole 81s is formed in the interlayer insulation layer 212 and the spacer SP as shown in FIG. 8. The trench TR2 passes through the contact 71s as viewed from a direction substantially perpendicular to the wiring layer L. The trench TR2 is formed through the same process as that illustrated in FIG. 6C.

Further, the trench TR3 passing through the contact hole 81s is formed. The trench TR3 has a width larger than the width of the trench TR2. The trench TR3 passes through the contact 71s as viewed from a direction substantially perpendicular to the wiring layer L. The trench TR3 is formed through the same processes as those illustrated in FIG. 6D and FIG. 6E. Note that the trenches TR2 and TR3 are formed and the opening Spa is also formed in the spacer SP on the sacrificial film SAC.

Furthermore, the sacrificial film SAC is removed. In addition, pretreatment for metal film deposition is performed.

Thereafter, the barrier metal layer BM and the conductive layer 61s are embedded in the contact hole 81s and the trenches TR2 and TR3. In this manner, the contact 71s and the wiring D0 are formed. Further, CMP is performed so as to expose the interlayer insulation layer 212.

In this way, the semiconductor device 1 illustrated in FIG. 7 is manufactured.

As in the third embodiment, the side surface of the wiring D0 may be in a step shape. This case also allows the same effects as those of the first embodiment to be obtained.

### Fourth Embodiment

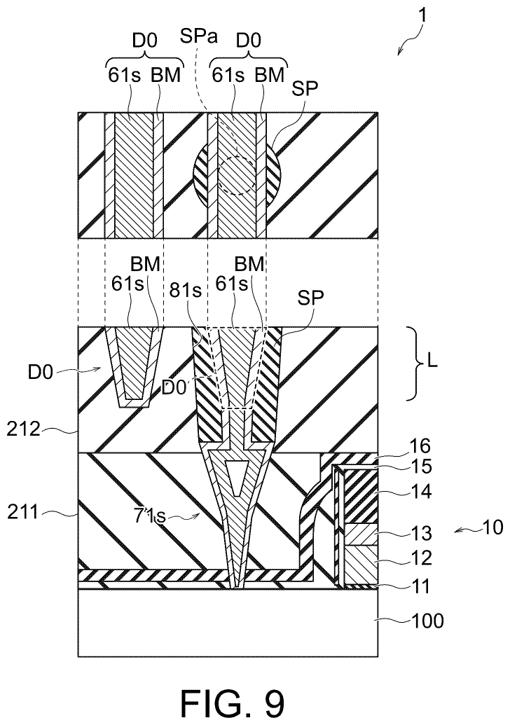

FIG. 9 is a cross-sectional view illustrating an example of the configuration of the semiconductor device 1 according to a fourth embodiment. The fourth embodiment is different from the first embodiment in that the width of the lower end of the contact 71s is smaller than the width of the upper end of the contact 71s.

As in the fourth embodiment, the width of the lower end of the contact 71s may be smaller than the width of the upper end of the contact 71s. This case also allows the same effects as those of the first embodiment to be obtained. Further, the second embodiment or the third embodiment may be combined with the semiconductor device 1 according to the fourth embodiment.

### Application Example of Semiconductor Device

The configuration of the above-described embodiments and the modifications can be applied to, for example, a transistor or the like provided around a memory cell of a semiconductor memory device and constituting a drive circuit for driving the memory cell. Hereinafter, a configuration example of a semiconductor memory device including a transistor to which the configuration of any one of the above-described embodiments and modifications is applied will be described with reference to the drawings.

### Schematic Configuration of Semiconductor Memory Device

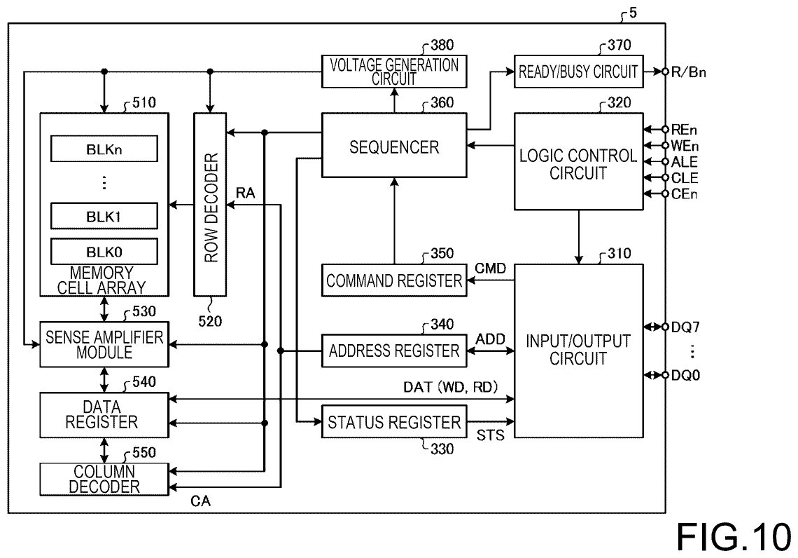

FIG. 10 is a block diagram of a semiconductor memory device 5 according to another embodiment. As illustrated in FIG. 10, the semiconductor memory device 5 includes an input/output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input/output circuit 310 controls input/output of a signal DQ to/from an external device such as a memory controller (not illustrated) that controls the semiconductor memory device 5. The input/output circuit 310 includes an input circuit and an output circuit (not illustrated).

The input circuit transmits data DAT such as write data WD received from the external device to the data register 540, transmits address ADD to the address register 340, and transmits command CMD to the command register 350.

The output circuit transmits status information STS received from the status register 330, data DAT such as read data RD received from the data register 540, and address ADD received from the address register 340 to the external device.

The logic control circuit 320 receives, for example, a chip enable signal CEn, a command latch enable signal CLE, an address latch enable signal ALE, a write enable signal WEn, and a read enable signal REn from an external device. In addition, the logic control circuit 320 controls the input/output circuit 310 and the sequencer 360 in accordance with the received signal.

The status register 330 temporarily holds status information STS in, for example, a write operation, a read operation, and an erase operation of data, and notifies whether or not the operation is normally ended to the external device.

The address register 340 temporarily holds the address ADD received from the external device via the input/output circuit 310. In addition, the address register 340 transfers a row address RA to the row decoder 520 and transfers a column address CA to the column decoder 550.

The command register 350 temporarily stores the command CMD received from the external device via the input/output circuit 310 and transfers the command CMD to the sequencer 360.

The sequencer 360 controls the entire operation of the semiconductor memory device 5. More specifically, the sequencer 360 controls, for example, the status register 330, the ready/busy circuit 370, the voltage generation circuit 380, the row decoder 520, the sense amplifier module 530, the data register 540, the column decoder 550, and the like in accordance with the command CMD held by the command register 350, and executes a write operation, a read operation, an erase operation, and the like.

The ready/busy circuit 370 transmits a ready/busy signal R/Bn to an external device in accordance with the operation status of the sequencer 360.

The voltage generation circuit 380 generates a voltage necessary for the write operation, the read operation, and the erase operation in accordance with the control of the sequencer 360, and supplies the generated voltage to, for example, the memory cell array 510, the row decoder 520, the sense amplifier module 530, and the like. The row decoder 520 and the sense amplifier module 530 apply the voltage supplied from the voltage generation circuit 380 to the memory cells in the memory cell array 510.

The memory cell array 510 includes a plurality of blocks BLK (BLK0 to BLKn). “n” is an integer of 2 or more. The block BLK is a set of a plurality of memory cells associated with bit lines and word lines, and is, for example, a data erasing unit. The memory cell is configured as, for example, a transistor, and holds nonvolatile data.

By including such a memory cell, the semiconductor memory device 5 is configured as, for example, a NAND nonvolatile memory. However, the semiconductor memory device 5 may be configured as, for example, another non-volatile memory of a NOR type or the like.

The row decoder 520 decodes the row address RA. In addition, the row decoder 520 selects any block BLK on the basis of the decoding result. Further, the row decoder 520 applies a necessary voltage to the block BLK.

The sense amplifier module 530 senses data read from the memory cell array 510 during the read operation. In addition, the sense amplifier module 530 transmits the read data RD to the data register 540. During the write operation, the sense amplifier module 530 transmits the write data WD to the memory cell array 510.

The data register 540 includes a plurality of latch circuits. The latch circuit holds the write data WD and the read data RD. For example, in the write operation, the data register 540 temporarily holds the write data WD received from the input/output circuit 310 and transmits the write data WD to the sense amplifier module 530. In addition, for example, in the read operation, the data register 540 temporarily holds the read data RD received from the sense amplifier module 530 and transmits the read data RD to the input/output circuit 310.

The column decoder 550 decodes the column address CA at the time of, for example, the write operation, the read operation, and the erase operation, and selects the latch circuit in the data register 540 in accordance with the decoding result.

Note that each of the above-described components of the semiconductor memory device 5 excluding the memory cell array 510 are also referred to as a peripheral circuit. The peripheral circuit is a circuit group arranged around the memory cell array 510, and includes the input/output circuit 310, the logic control circuit 320, the status register 330, the address register 340, the command register 350, the sequencer 360, the ready/busy circuit 370, the voltage generation circuit 380, the row decoder 520, the sense amplifier module 530, the data register 540, and the column decoder 550.

As described above, the semiconductor memory device 5 includes the memory cell array 510 including the plurality of memory cells and the peripheral circuit that operates the plurality of memory cells.

### Circuit Configuration of Memory Cell Array and Row Decoder

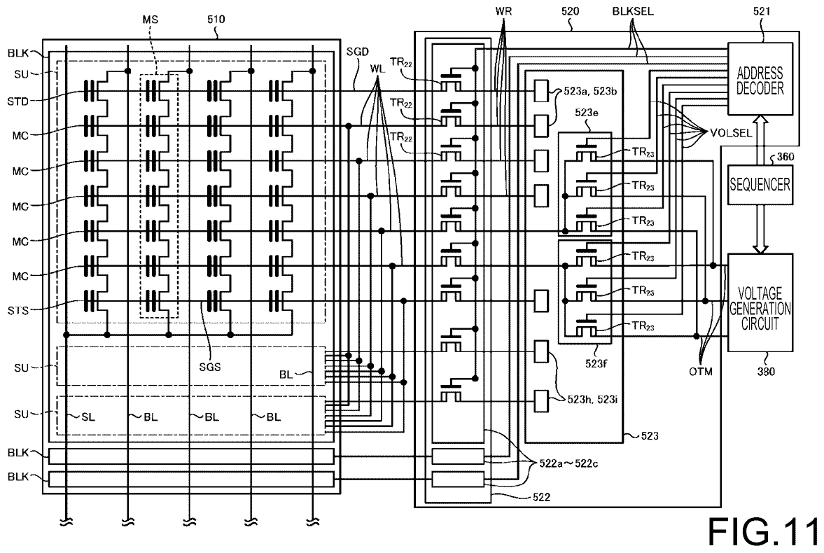

FIG. 11 is an equivalent circuit diagram illustrating an example of the configuration of the memory cell array 510 and the row decoder 520 included in the semiconductor memory device 5 according to another embodiment. First, an example of a circuit configuration of the memory cell array 510 included in the semiconductor memory device 5 will be described below.

The memory cell array 510 includes the plurality of blocks BLK as described above. Each of the plurality of blocks BLK includes a plurality of string units SU. Each of the plurality of string units SU includes a plurality of memory strings MS. One end of each of the plurality of memory strings MS is connected to a peripheral circuit such as the row decoder 520 and the sense amplifier module 530 via a bit line BL. The other end of each of the plurality of memory strings MS is connected to a peripheral circuit via a common source line SL.

The memory string MS includes a drain selection transistor STD connected in series between the bit line BL and the source line SL, a plurality of memory cells MC, and a source selection transistor STS. Hereinafter, the drain selection transistor STD and the source selection transistor STS may be occasionally simply referred to as selection transistors (STD, STS).

The memory cell MC is, for example, a field effect transistor (FET) including a charge storage layer in a gate insulation layer. A threshold voltage of the memory cell MC changes in accordance with a charge amount in the charge storage layer. With one or a plurality of threshold voltages provided, the memory cell MC may be capable of storing data of one bit or a plurality of bits. The word line WL is connected to each gate electrode of the plurality of memory cells MC corresponding to one memory string MS. Each of these word lines WL is commonly connected to all the memory strings MS in one block BLK.

The selection transistor (STD, STS) is, for example, a field effect transistor. A selection gate line (SGD, SGS) is connected to each gate electrode of the selection transistor (STD, STS). The drain selection line SGD connected to the drain selection transistor STD is provided corresponding to the string unit SU, and is commonly connected to all the memory strings MS in one string unit SU. The source selection line SGS connected to the source selection transistor STS is commonly connected to all the memory strings MS in one block BLK.

Next, a circuit configuration of the row decoder 520 included in the semiconductor memory device 5 will be described.

The row decoder 520 includes an address decoder 521, a block selection circuit 522, and a voltage selection circuit 523. The row decoder 520 includes, in these circuits, for example, transistors TR₂₂ and TR₂₃ and the like to which the configuration of any one of the above-described embodiments and modifications is applied.

The address decoder 521 includes a plurality of block selection lines BLKSEL and a plurality of voltage selection lines VOLSEL.

The address decoder 521 refers to the address data of the address register 340 (see FIG. 10) included in the above-described peripheral circuit, for example, in accordance with a control signal from the sequencer 360.

Furthermore, the address decoder 521 decodes the referred address data, turns on the transistor TR₂₂ and the transistor TR₂₃ corresponding to the address data, and turns off the other transistors TR₂₂ and TR₂₃. Note that the transistor TR₂₂ and the transistor TR₂₃ are transistors included respectively in the block selection circuit 522 and the voltage selection circuit 523, which will be described later.

Further, the address decoder 521 sets the voltages of the block selection line BLKSEL and the voltage selection line VOLSEL corresponding to the address data to, for example, an “H” state, and sets the other voltages to an “L” state.

In the example of FIG. 11, in the address decoder 521, one block selection line BLKSEL is provided for each block BLK in the memory cell array 510. However, this configuration can be changed as appropriate. For example, one block selection line BLKSEL may be provided for each of two or more blocks BLK.

The block selection circuit 522 includes a plurality of block selector 522a to 522c corresponding to the blocks BLK of the memory cell array 510, respectively. Each of the plurality of block selectors 522a to 522c includes a plurality of transistors TR₂₂ corresponding to the word lines WL and the selection gate lines (SGD, SGS).

The transistor TR₂₂ is, for example, a high-voltage N-channel MOS transistor, and functions as a block drive transistor. The drain electrodes of the transistors TR₂₂ are each electrically connected to the corresponding word line WL or selection gate line (SGD, SGS). The source electrodes of the transistors TR₂₂ are each electrically connected to a voltage output terminal OTM via a wiring WR and the voltage selection circuit 523. The gate electrodes of the transistors TR₂₂ are commonly connected to the corresponding block selection line BLKSEL.

Furthermore, the block selection circuit 522 further includes a plurality of transistors (not illustrated). The plurality of transistors is a high-voltage CMOS transistor connected between the selection gate line (SGD, SGS) and a ground voltage supply terminal. The plurality of transistors causes the selection gate line (SGD, SGS) included in the unselected block BLK in the memory cell array 510 to conduct with the ground voltage supply terminal. Note that the plurality of word lines WL included in the unselected block BLK turns into a floating state.

The voltage selection circuit 523 includes a plurality of voltage selectors 523a to 523i corresponding to the word lines WL and the selection gate lines (SGD, SGS). Each of the plurality of voltage selectors 523a to 523i includes a plurality of transistors TR₂₃.

The transistor TR₂₃ is a high-voltage N-channel MOS transistor, and functions as a voltage selection transistor. Each of the drain terminals of the transistor TR₂₃ is electrically connected to the corresponding word line WL or selection gate line (SGD, SGS) via the wiring WR and the block selection circuit 522. Each of the source terminals is electrically connected to the corresponding voltage output terminal OTM. Each of the gate electrodes is connected to the corresponding voltage selection line VOLSEL.

As described above, the row decoder 520 belonging to the peripheral circuit includes the plurality of transistors TR₂₂, TR₂₃, and the like. These transistors TR₂₂ and TR₂₃ are transistors that are arranged in the row decoder 520 at a high density and serve as main components of the row decoder 520.

However, the circuit configuration of the row decoder 520 illustrated in FIG. 11 is an example, and the number and types of the transistors TR₂₂ and TR₂₃ and the like included in the row decoder 520 may variously differ.

Further, other than the above, the row decoder 520 also includes a high-voltage P-channel MOS transistor, a low-voltage P-channel MOS transistor, and the like that are auxiliary components of the row decoder 520.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a wiring layer including a plurality of wirings; and
a columnar electrode provided integrally with the wiring, the columnar electrode extending from a bottom of the wiring in a direction substantially perpendicular to the wiring layer,
wherein a width of an upper end of the columnar electrode is smaller than a width of a middle portion between the upper end and a lower end of the columnar electrode.

2. The semiconductor device according to claim 1, wherein a position at which the width of the columnar electrode is largest is situated lower relative to the bottom of the wiring along the direction substantially perpendicular to the wiring layer.

3. The semiconductor device according to claim 1, further comprising a spacer provided on a side surface of the wiring on an upper side of the columnar electrode and a side surface of the upper end of the columnar electrode.

4. The semiconductor device according to claim 1, wherein the wiring has a step shape with an upper step having a width larger than a width of a lower step.

5. A manufacturing method of a semiconductor device, the manufacturing method comprising:
forming a hole in a first insulation layer;
embedding a sacrificial film in the hole;
removing a part of the sacrificial film in the hole;
forming a spacer on an inner side surface of the hole and on the sacrificial film;
forming a trench passing through the hole and forming an opening in the spacer on the sacrificial film;
removing the sacrificial film via the opening; and
embedding a conductive layer in the hole and the trench to form a columnar electrode and a wiring.

6. The manufacturing method of a semiconductor device according to claim 5,
wherein the forming the trench comprises:
forming a first trench passing through the hole; and
forming a second trench passing through the hole, the second trench having a width larger than a width of the first trench.

7. A semiconductor device comprising:
a wiring layer including a plurality of wirings; and
a columnar electrode extending from a bottom of the wiring in a direction substantially perpendicular to the wiring layer,
wherein the wiring has a step shape with an upper step having a width larger than a width of a lower step.

8. The semiconductor device according to claim 7, further comprising a barrier metal layer provided between the columnar electrode and the wiring on an upper side of the columnar electrode.

9. The semiconductor device according to claim 7, wherein a tip end of the wiring reaches the columnar electrode.

10. A manufacturing method of a semiconductor device, the manufacturing method comprising:
forming a hole in a first insulation layer;
embedding a conductive layer in the hole to form a columnar electrode;
forming a second insulation layer on the first insulation layer;
forming a first trench passing through the hole in the second insulation layer;
forming, in the second insulation layer, a second trench passing through the hole and having a width larger than a width of the first trench so as to allow the first trench to reach the columnar electrode; and
embedding a conductive layer in the first trench and the second trench to form a wiring.
